(19) United States
(12) Patent Application Publication
(10) Pub. No.: US 2006/0284259 A1
(43) Pub. Date: Dec. 21, 2006

(54) Semiconductor device and method of manufacturing the same

(76) Inventors: Jung-Hyeon Lee, Yongin-si (KR); Si-Hyeung Lee, Hwaseong-si (KR); Kwang-Sub Yoon, Seoul (KR); Bong-Cheol Kim, Seoul (KR)

Correspondence Address: HARNESS, DICKEY & PIERCE, P.L.C., P.O. BOX 8910, RESTON, VA, 20195, US

(21) Appl. No.: 11/449,689

(22) Filed: Jun. 9, 2006

(30) Foreign Application Priority Data
Jun. 16, 2005 (KR) 2005-52015

(51) Int. Cl. H01L 29/76

(52) U.S. Cl. 257/365

(57) ABSTRACT

In a semiconductor device having asymmetric bit lines and a method of manufacturing the same, a plurality of active regions are electrically isolated from one another by an isolation layer. Each active region extends in a first direction and has a central portion between end portions. The device includes a plurality of transistors, each including first impurity doped regions formed at the central portions and second impurity doped regions formed at both end portions to extend in a second direction different from the first direction. A plurality of asymmetric bit lines are electrically connected to the first impurity doped regions, each extending in a third direction substantially perpendicular to the second direction. Each asymmetric bit line has a first side surface extending in a straight line along the third direction, and a second side surface including a plurality of protrusions.

### PRIORITY STATEMENT

This application claims the benefit under 35 USC §119 of Korean Patent Application No. 2005-52015, filed on Jun. 16, 2005 in the Korean Intellectual Property Office (KIPO), the entire contents of which is hereby incorporated by reference herein.

### BACKGROUND OF THE INVENTION

1. Field of the Invention

Example embodiments of the present invention relate to a semiconductor device having active regions, word lines and bit lines extending in directions different from one another, and to a method of manufacturing the same.

2. Description of the Related Art

A semiconductor device such as a dynamic random access memory (DRAM), in general, includes a plurality of transistors and a plurality of capacitors electrically connected to the transistors to store data. The transistors are formed on active regions defined in a surface portion of a semiconductor substrate and connected to the capacitors by contact pads and contact plugs.

As a packing density of the semiconductor device has become more highly integrated, a unit cell size of the semiconductor device has become substantially reduced. Various attempts have been made to compensate this reduction in unit cell size, including the development of an ultra-fine process, structural changes of the unit cell, etc.

FIGS. 1 to 4 are plan views illustrating a layout of a semiconductor device in accordance with a conventional manufacturing process.

Referring to FIG. 1, a plurality of active regions 12 extending in a first direction are formed in a surface portion of a semiconductor substrate 10. The active regions 12 may be defined by an isolation layer 14. As shown in FIG. 1, a central portion of each active region 12 is disposed between end portions of an adjacent pair of active regions 12. In other words, a given active region 12 is disposed at a point symmetrical position with respect to a center point of any one of the other active regions 12.

Referring to FIG. 2, gate insulating layer patterns (not shown) and word line structures 20 are formed on the semiconductor substrate 10. The word line structures 20 extend in a second direction different from the first direction in which the active regions 12 extend, and intersect the active regions 12. As shown in FIG. 2, a given active region 12 intersects two word line structures 20. The word line structures 20 include word lines formed on the gate insulating layer patterns to serve as gate electrodes, gate mask patterns (not shown) formed on the word lines and gate spacers (not shown) formed on side surfaces of the word lines and gate mask patterns.

Though not shown in the figures, impurity doped regions serving as source/drain regions of transistors are formed at surface portions of the semiconductor substrate 10 adjacent to the word line structures 20. In an example, two transistors are formed on each active region 12. A first impurity doped region is formed at a central portion of each active region 12 and is associated with the two transistors, and two second impurity doped regions are formed at both end portions of each active region 12.

Referring to FIG. 3, bit line structures 30 are formed above the word line structures 20 and are electrically connected to the first impurity doped regions. The bit line structures 30 extend in a third direction substantially perpendicular to the word line structures 20 and intersect the central portions of the active regions 12.

Although not specifically shown in FIG. 3, the bit line structures 30 are electrically connected to the first impurity doped regions by first contact pads and direct contact plugs (or bit line contact plugs) formed on the first impurity doped regions. Each of the bit line structures 30 include expanded portions having a relatively large width, and which are positioned just above the first impurity doped regions so as to facilitate the electrical connection with the first impurity doped regions.

Referring to FIG. 4, capacitors (not shown) are formed above the bit line structures 30 to store data Each capacitor includes a storage node electrode, a dielectric layer and a plate electrode. The storage node electrodes are electrically connected to the second impurity doped regions formed at the end portions of the active regions. For example, the storage node electrodes are electrically connected to the second impurity doped regions by second contact pads and buried contact plugs 50 (or storage node contact plugs) formed on the second impurity doped regions. In FIG. 4, reference numeral 40 represents positions at which the storage node electrodes will be formed.

The buried contact plugs 50 extend upward from the substrate 10 between the bit line structures 30, and the storage node electrodes are formed above the bit line structures 30. However, each of the storage node electrodes is formed at a position adjacent to the buried contact plugs 50 connected to one or more adjacent storage node electrodes, so that an electrical bridge is formed therebetween. That is, the electrical bridge may be formed between capacitors connected to the second impurity doped regions of adjacent active regions 12. As shown in FIG. 4, the electric bridge is formed because a distance DI, between the buried contact plug 50 self-aligned by the bit line structures 30 and the adjacent storage node electrode, is substantially narrow. Particularly, there is a substantial possibility that an electric bridge will be formed in a region A, as shown in FIG. 4. In other words, the electrical bridge results from the shape of the bit line structures 30, and occurs because an alignment margin cannot be stably secured between the buried contact plugs 50, self-aligned by the bit line structures 30, and the storage node electrodes 40.

### SUMMARY OF THE INVENTION

An example embodiment of the present invention is directed to a semiconductor device including a substrate, a plurality of transistors and a plurality of asymmetric bit lines. The substrate has a plurality of active regions isolated from one another by an isolation layer and extending in a first direction. Each active region has a central portion between end portions. The transistors include first impurity doped regions formed at the central portions, second impurity doped regions formed at both end portions, gate insulating layer patterns formed between the first impurity doped regions and the second impurity doped regions, and word lines formed on the gate insulating layer patterns, to extend in a second direction different from the first direction. The asymmetric bit lines are electrically connected to the first impurity doped regions. Each of the asymmetric bit lines extends in a third direction substantially perpendicular to the second direction, has a first side surface extending in a straight line along the third direction, and has a second side surface including a plurality of protrusions.

Another example embodiment of the present invention is directed to a method of manufacturing a semiconductor device. In the method, an isolation layer is formed on a substrate to define a plurality of active regions. Each active region extends in a first direction and has a central portion between end portions. A plurality of gate insulating patterns and word lines are formed between the central portions and end portions of the active regions. The word lines extend in a second direction different from the first direction. A plurality of first impurity doped regions are formed at the central portions, and a plurality of second impurity doped regions are formed at the end portions of the active regions. A plurality of asymmetric bit lines are formed so as to be electrically connected to the first impurity doped regions. Each of the symmetric bit lines extends in a third direction substantially perpendicular to the second direction, has a first side surface extending in a straight line along the third direction, and has a second side surface including a plurality of protrusions.

### BRIEF DESCRIPTION OF THE DRAWINGS

Example embodiments of the present invention will become readily apparent along with the following detailed description when considered in conjunction with the accompanying drawings.

FIGS. 1 to 4 are plan views illustrating a layout of a semiconductor device in accordance with a conventional manufacturing process.

FIG. 5 is a plan view illustrating active regions defined in a semiconductor substrate, according to an example embodiment of the present invention.

FIG. 6 is a cross-sectional view taken along extension direction of the active regions of FIG. 5, according to an example embodiment of the present invention.

FIG. 7 is a plan view illustrating word line structures formed on the semiconductor substrate of FIG. 5, according to an example embodiment of the present invention.

FIG. 8 is a cross-sectional view taken along the extension direction of the active regions to illustrate the word line structures of FIG. 7, according to an example embodiment of the present invention.

FIG. 9 is a plan view illustrating first and second contact pads formed on impurity doped regions of the active regions of FIG. 8, according to an example embodiment of the present invention.

FIG. 10 is a cross-sectional view taken along the extension direction of the active regions to illustrate the first and second contact pads of FIG. 9, according to an example embodiment of the present invention.

FIG. 11 is a plan view illustrating bit line structures electrically connected to the first contact pads of FIG 10, according to an example embodiment of the present invention.

FIG. 12 is a cross-sectional view taken along the extension direction of the active regions to illustrate the bit line structures of FIG. 11, according to an example embodiment of the present invention.

FIG. 13 is a cross-sectional view taken along extension direction of the word line structures to illustrate the bit line structures of FIG. 11, according to an example embodiment of the present invention.

FIG. 14 is a plan view illustrating storage node contact plugs formed between the bit line structures of FIG. 11, according to an example embodiment of the present invention.

FIG. 15 is a cross-sectional view taken along the extension direction of the word line structures to illustrate the storage node contact plugs of FIG. 14, according to an example embodiment of the present invention.

FIG. 16 is a plan view illustrating a mold layer having openings exposing the storage node contact plugs of FIG. 15, according to an example embodiment of the present invention.

FIG. 17 is a cross-sectional view taken along the extension direction of the word line structures to illustrate the mold layer of FIG. 16, according to an example embodiment of the present invention.

FIG. 18 is a plan view illustrating storage node electrodes formed in the openings of the mold layer of FIG. 17, according to an example embodiment of the present invention.

FIG. 19 is a cross-sectional view taken along the extension direction of the word line structures to illustrate the storage node electrodes of FIG. 18, according to an example embodiment of the present invention.

FIG. 20 is a cross-sectional view illustrating capacitors formed on the storage node contact plugs of FIG. 19, according to an example embodiment of the present invention.

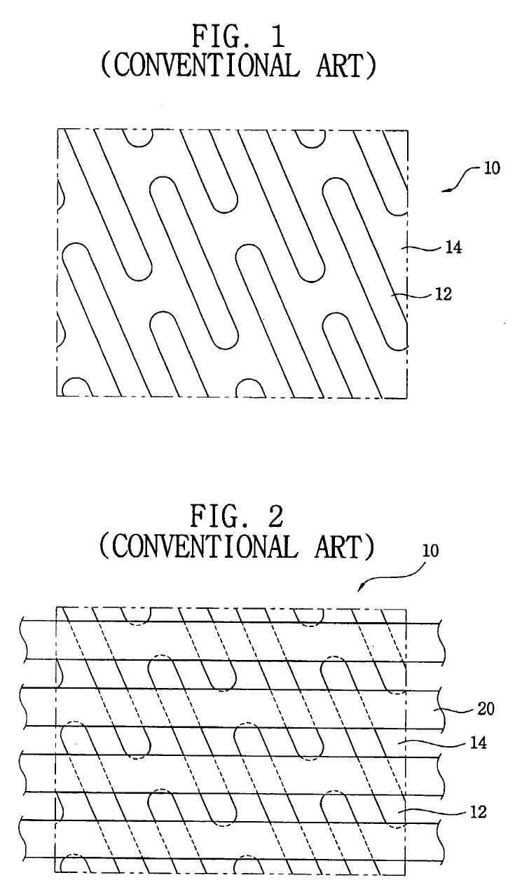

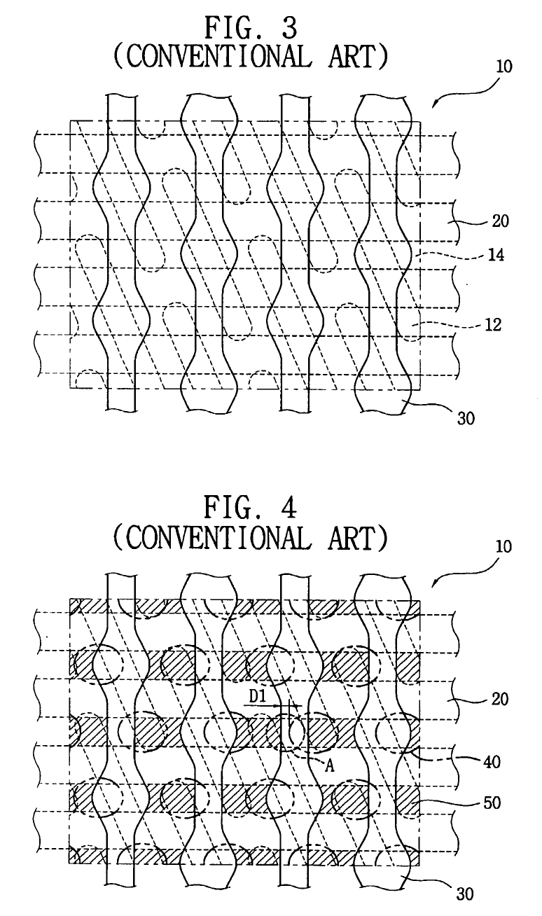

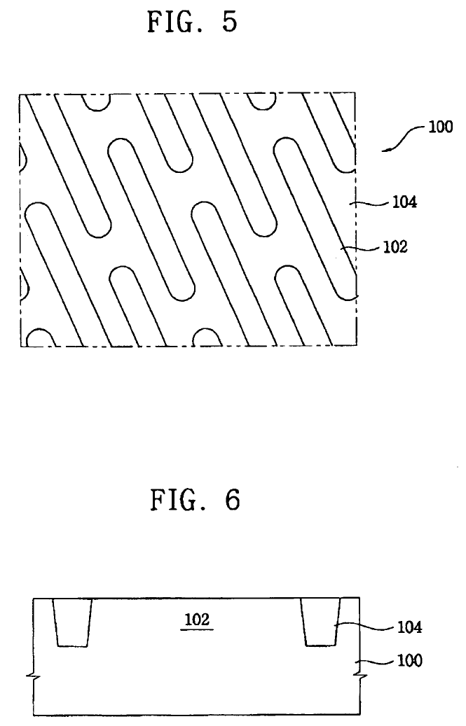

### DETAILED DESCRIPTION OF EXAMPLE EMBODIMENTS

The invention now will be described more fully hereinafter with reference to the accompanying drawings, in which example embodiments of the invention are shown. This invention may, however, be embodied in many different forms and should not be construed as limited to the example embodiments set forth herein. Rather, these example embodiments are provided so that this disclosure will be thorough and complete, and will fully convey the scope of the invention to those skilled in the art. Like reference numerals refer to like elements throughout.

As used herein, when an element is referred to as being “on” another element, it can be directly on the other element or intervening elements may be present. In contrast, when an element is referred to as being “directly on” another element, no intervening elements are present. As used herein, the term “and/or” includes any and all combinations of one or more of the associated listed items.

Although the terms first, second, etc. may be used herein to describe various elements, these elements should not be limited by these terms. These terms are used merely to distinguish one element from another. For example, a first thin film could be termed a second thin film, and, similarly, a second thin film could be termed a first thin film without departing from the teachings of the disclosure.

The terminology used herein is for the purpose of describing particular example embodiments only, and is not intended to be limiting of the example embodiments of the invention. As used herein, the singular forms “a”, “an” and “the” may include the plural forms as well, unless the context clearly indicates otherwise. Further, the terms “comprises” and/or “comprising,” or “includes” and/or “including,” when used in this specification, specify the presence of stated features, regions, integers, steps, operations, elements, and/or components, but do not preclude the presence or addition of one or more other features, regions, integers, steps, operations, elements, components, and/or groups thereof.

Relative terms such as “lower” or “bottom” and “upper” or “top” may be used herein to describe one element's relationship to another elements as illustrated in the Figures. It will be understood that relative terms are intended to encompass different orientations of the device, in addition to the orientation depicted in the Figures. For example, if the device in one of the figures is turned over, elements described as being on the “lower” side of other elements would then be oriented on “upper” sides of the other elements. The term “lower” can therefore encompass both an orientation of “lower” and “upper,” depending of the particular orientation of the figure. Similarly, if the device in one of the figures is turned over, elements described as “below” or “beneath” other elements would then be oriented “above” the other elements. The terms “below” or “beneath” may therefore encompass both an orientation of above and below.

Unless otherwise defined, terms (including technical and scientific terms) used herein have the same meaning as commonly understood by one of ordinary skill in the art to which this invention belongs. Moreover, terms, such as those defined in commonly used dictionaries should be interpreted as having a meaning that is consistent with the term's meaning in the context of the relevant art and the present disclosure, and will not be interpreted in an idealized or overly formal sense unless so expressly defined herein.

Example embodiments of the present invention are described herein with reference to cross-section illustrations that are schematic illustrations of idealized embodiments of the present invention. As such, variations from the shapes of the illustrations as a result, for example, of manufacturing techniques and/or tolerances, are to be expected. Thus, the example embodiments of the present invention should not be construed as limited to the particular shapes of regions illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and the shapes are not intended to illustrate the precise shape of a region, and thus are not intended to limit the scope of the example embodiments of the present invention.

As to be described in more detail below, FIGS. 5 to 20 are views for illustrating a method of manufacturing a semiconductor device, in accordance with an example embodiment of the present invention.

FIG. 5 is a plan view illustrating active regions defined in a semiconductor substrate, and FIG. 6 is a cross-sectional view taken along an extension direction of the active regions as shown in FIG. 5.

Referring to FIGS. 5 and 6, an isolation layer 104 is formed on a semiconductor substrate 100 such as a silicon wafer so as to define active regions 102 in the semiconductor substrate 100. A silicon wafer is one example of a substrate 100, various oxides of silicon or other equivalent materials may be used for substrate 100. For example, the isolation layer 104 may be formed by a shallow trench isolation (STI) process to electronically isolate the active regions 102 from one another. The active regions 102 extend in a first direction on the semiconductor substrate 100. Each of the active regions 102 has a first end portion and a second end portion. As shown in FIG. 5, a central portion of each active region 102 is disposed between the first end portion and the second end portion of the adjacent active regions 102, i.e., disposed at point symmetrical positions with respect to a center point of any adjacent one of the active regions 102.

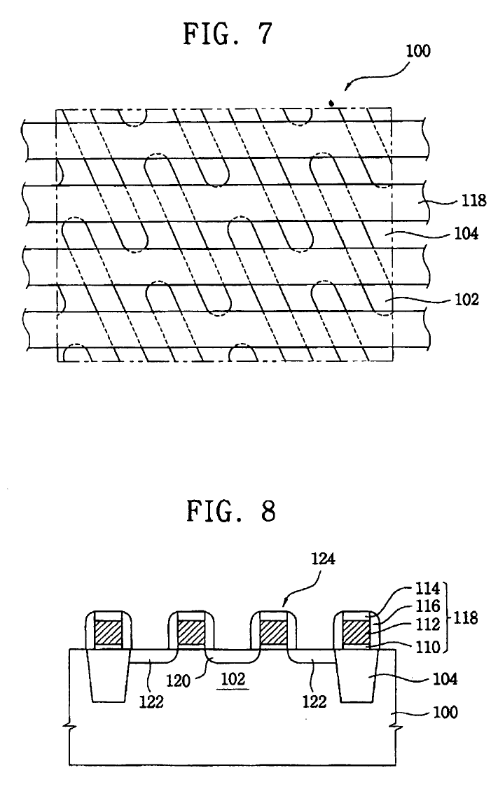

FIG. 7 is a plan view illustrating word line structures formed on the semiconductor substrate as shown in FIG. 5, and FIG. 8 is a cross-sectional view taken along the extension direction of the active regions to illustrate the word line structures of FIG. 7.

Referring to FIGS. 7 and 8, a gate insulating layer having a thin thickness is formed on the active regions 102 and the isolation layer 104. A silicon oxide layer formed by a thermal oxidation process or a chemical vapor deposition (CVD) process may be used as the gate insulating layer. These processes are merely exemplary, other processes may be used to form the silicon oxide layer as is evident to one of ordinary skill in the art.

A first conductive layer, serving as a gate conductive layer, and a first mask layer, serving as a gate mask layer, are sequentially formed on the gate insulating layer. An impurity doped polysilicon layer may be used as the gate conductive layer, and a metal silicide layer may be further formed on the impurity doped polysilicon layer. The first mask layer may include a material having an etching selectivity with respect to a subsequently formed first insulation interlayer. For example, if the first insulation interlayer includes silicon oxide, the first mask layer may include silicon nitride.

After forming a first photoresist pattern on the first mask layer, the first mask layer, first conductive layer and gate insulating layer are sequentially patterned by an etching process using the first photoresist pattern as an etching mask, thereby forming gate insulating layer patterns 110, word lines 112 serving as gate electrodes, and gate mask patterns 114 on the semiconductor substrate 100. The etching process may be performed until surfaces of the active regions 102 are exposed. The first photoresist pattern is removed by ashing and stripping processes, for example.

Alternatively, the gate mask patterns 114 may be formed on the first conductive layer by an etching process using the first photoresist pattern as an etching process. Then, after removing the first photoresist pattern, the word lines 112 and the gate insulating layer patterns 110 may be formed by an etching process using the gate mask patterns 114 as etching masks.

A first spacer layer (not shown in FIG. 8) is formed on the semiconductor substrate 100, on which the gate insulating layer patterns 110, the word lines 112 and the gate mask patterns 114 have been formed. The first spacer layer is anisotropically etched away so as to form gate spacers 116 on the gate mask patterns 114, the word lines 112 and the gate insulating layer patterns 110, collectively constituting word line structures 118 on the semiconductor substrate 100, as shown in FIG. 8.

As can be seen in FIG. 7, the word line structures 118 extend in a second direction different from the extension direction of the active regions 102. Each of the active regions 102 intersects two word line structures 118. The word line structures 118 have cross-channel regions between the central portion and both end portions of a given active region 102, which exposes the central portions and end portions of the active regions 102.

By forming first impurity doped regions 120 at central portions of the active regions and second impurity doped regions 122 at both end portions of the active regions 102, a plurality of transistors 124 may be formed. The first impurity doped regions 120 serve as a source region of a given transistors 124 and the second impurity doped regions 122 serve as the drain regions of the transistor 124. Two transistors 124 having one first impurity doped region 120 in common therebetween may be constituted at each of the active regions 102.

Each of the first and second impurity doped regions 120 and 122 may include a lightly-doped region and a heavily-doped region, and each of the lightly and heavily-doped regions may be formed before and after forming the gate spacers 116 (i.e., one of the lightly-doped or heavy-doped regions formed prior to forming gate spacers 116, with the other regions formed after).

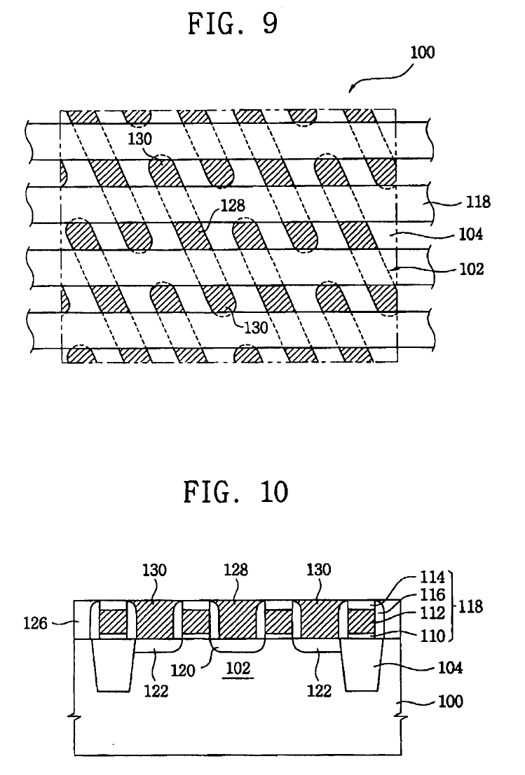

FIG. 9 is a plan view illustrating first and second contact pads formed on impurity doped regions of the active regions as shown in FIG. 8, and FIG. 10 is a cross-sectional view taken along the extension direction of the active regions to illustrate the first and second contact pads of FIG. 9.

Referring to FIGS. 9 and 10, a first insulation interlayer 126 is formed on the semiconductor substrate 100 on which the word line structure 118 is formed. The first insulation interlayer 126 may include a silicon oxide such as borophosphosilicate glass (BPSG), phosphosilicate glass (PSG), undoped silicate glass (USG), tetraethyl orthosilicate (TEOS) oxide, high density plasma chemical vapor deposition (HDP-CVD) oxide, etc. The first insulation interlayer 126 may be formed so as to fill up interspaces between the word line structures 118. A chemical mechanical polishing (CMP) process is performed to planarize the first insulation interlayer 126 so as to expose the gate mask patterns 114.

A second photoresist pattern is formed on the planarized first insulation interlayer 126. First and second contact holes (not shown) exposing the first and second impurity regions 120 and 122 may then be formed by performing an etching process using the second photoresist pattern as an etching mask. The first and second contact holes may be self-aligned to the first and second impurity regions 120 and 122 by providing an etch rate differential between the gate spacers 116 and the first insulation interlayer 126. The word lines 112 may be protected by the gate mask patterns 114 and the gate spacers 116 during the etching process for forming the first and second contact holes.

After removing the second photoresist pattern, a second conductive layer (not shown) is formed on the first insulation interlayer 126 and the gate mask patterns 114 in an effort to sufficiently fill up the first and second contact holes. The second conductive layer may include impurity doped polysilicon, a metal nitride such as titanium nitride, a metal such as tungsten, etc.

A surface portion of the second conductive layer is removed until the gate mask patterns 114 are exposed, to form first contact pads 128 and second contact pads 130 between the word line structures 118. The first and second contact pads 128, 130 are electrically connected to the first and second impurity regions 120 and 122. The surface portion of the second conductive layer may be removed by a CMP process or an etching back process, for example, although equivalent processes may be used for layer removal, as is known to one of ordinary skill in the art.

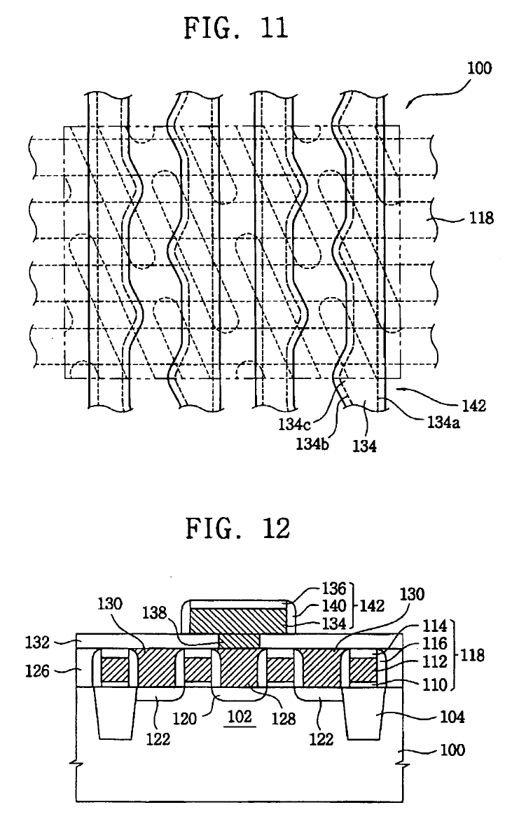

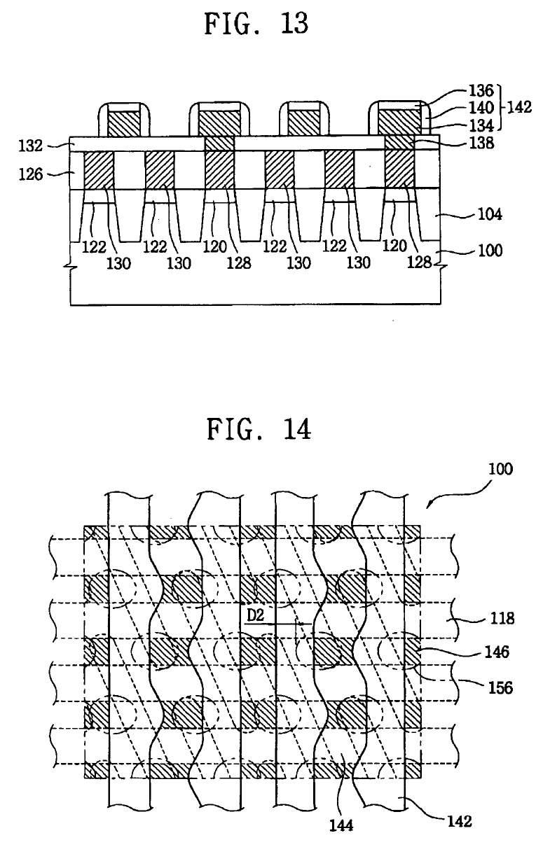

FIG. 11 is a plan view illustrating bit line structures electrically connected to the first contact pads as shown in FIG. 10. FIG. 12 is a cross-sectional view taken along the extension direction of the active regions to illustrate the bit line structures of FIG. 11, and FIG. 13 is a cross-sectional view taken along extension direction of the word line structures to illustrate the bit line structures of FIG. 11.

Referring to FIGS. 11 to 13, after forming the first and second contact pads 128 and 130, a second insulation interlayer 132 is formed on the first and second contact pads 128 and 130, the gate mask patterns 114 and the first insulation interlayer 126 so as to electrically isolate the word lines 112 from asymmetric bit lines. These symmetric bit lines will be subsequently formed on the second insulation interlayer 132. The second insulation interlayer 132 may comprise substantially the same material as the first insulation interlayer 126, for example.

A third photoresist pattern (not shown) is then formed on the second insulation interlayer 132, and an etching process is performed to form bit line contact holes (not shown) exposing the first contact pads 128 using the third photoresist pattern as an etching mask.

After forming the bit line contact holes, the third photoresist pattern is removed. A third conductive layer (not shown) is formed on the second insulation interlayer 132 so as to fill up the bit line contact holes, and a second mask layer (not shown) is formed on the third conductive layer. The second mask layer may comprise a material having an etching selectivity with respect to the second insulation interlayer 132. For example, the second mask layer may include silicon nitride, although other materials may be used for the second mask layer.

The third conductive layer may include a metal such as tungsten, a metal compound such as titanium nitride, etc. Alternatively, a metal barrier layer may be formed to prevent metal diffusion prior to forming the third conductive layer. A metal layer or a metal compound layer may be used as the metal barrier. For example, a composite layer including titanium and titanium nitride may be employed as the metal barrier layer.

After forming the second mask layer, a fourth photoresist pattern (not shown) is formed on the second mask layer, and then the second mask layer and third conductive layer are sequentially patterned by an etching process using the fourth photoresist pattern as an etching mask so as to form asymmetric bit lines 134. The asymmetric bit lines 134 are electrically connected to the first contact pads 128 and to bit line mask patterns 136 on the asymmetric bit lines 134. Here, the asymmetric bit lines 134 are electrically connected by bit line contact plugs 138 (or direct contact plugs) filled in the bit line contact holes.

Alternatively, the asymmetric bit lines 134 and the bit line contact plugs 138 may be formed separately. That is, after forming the bit line contact plugs 138, the asymmetric bit lines 134 may be formed. Further, after forming the bit line mask patterns 136 using the fourth photoresist pattern, the asymmetric bit lines 134 may be formed using the bit line mask patterns as etching masks. For example, the fourth photoresist pattern is removed before forming the asymmetric bit lines 134.

After forming the asymmetric bit lines 134 and the bit line mask patterns 136, a second spacer layer may be formed to a uniform thickness on the second insulation interlayer 132, the asymmetric bit lines 134 and the bit line mask patterns 136. An anisotropically etching process, for example, may be performed to form bit line spacers 140 on side walls of the asymmetric bit lines 134 and the bit line mask patterns 136, thereby constituting bit line structures 142. The second spacer layer may include a material having an etching selectivity with respect to a subsequently formed third insulation interlayer. For example, when the third insulation interlayer includes silicon oxide, the second spacer layer may include silicon nitride.

The bit line mask patterns 136 and the bit line spacers 140 are provided to electrically insulate the asymmetric bit lines 134 from storage node electrodes that are to be subsequently formed above the asymmetric bit lines 134.

As seen in FIG. 11, the bit line structures 142 extend in a third direction, substantially perpendicular to the word line structures 118, and intersect the central portions of the active regions 102. That is, the bit line structures 142 intersect over the first impurity doped regions 120 of the active regions 102.

Each of the asymmetric bit lines 134 may have a first side surface 134a extending in a straight line along the third direction. The straight edge first side surfaces 134a help to prevent an electrical bridge between storage node contact plugs (or buried contact plugs) to be subsequently formed between the bit line structures 142 and the storage node electrodes adjacent thereto. As also shown in FIG. 11, portions of the asymmetric bit lines 134 corresponding to the first contact pads 128 have an increased width, in an effort to increase an alignment margin between the asymmetric bit lines 134 and the first contact pads 128 formed on the first impurity doped regions 120. The increased width may be embodied by a plurality of protrusions 134c. The protrusions 134c may be formed on second side surfaces 134b opposite to the first side surfaces 134a of the asymmetric bit lines 134.

The first side surfaces 134a of adjacent asymmetric bit lines 134 are disposed so as to face each other as best seen in FIG. 11. The protrusions 134c formed on second side surfaces 134b protrude toward the second impurity doped regions 122. That is, the protrusions 134c protrude or extend in the second direction. Further, the second side surfaces 134b of adjacent asymmetric bit lines 134 are disposed or oriented so as to face each other. The protrusions 134c of the second side surfaces 134b may be further disposed in a zigzag orientation along the third direction, as best shown in FIG. 11, for example.

As described above, because each asymmetric bit line 134 has a first side surface 134a extending in a straight line and a second side surface 134b with protrusions 134c, an electric bridge may be prevented between capacitors to be subsequently formed above the asymmetric bit lines 134. In addition, a desirable and/or acceptable alignment margin between the asymmetric bit lines 134 and the first contact pads 128 may be secured.

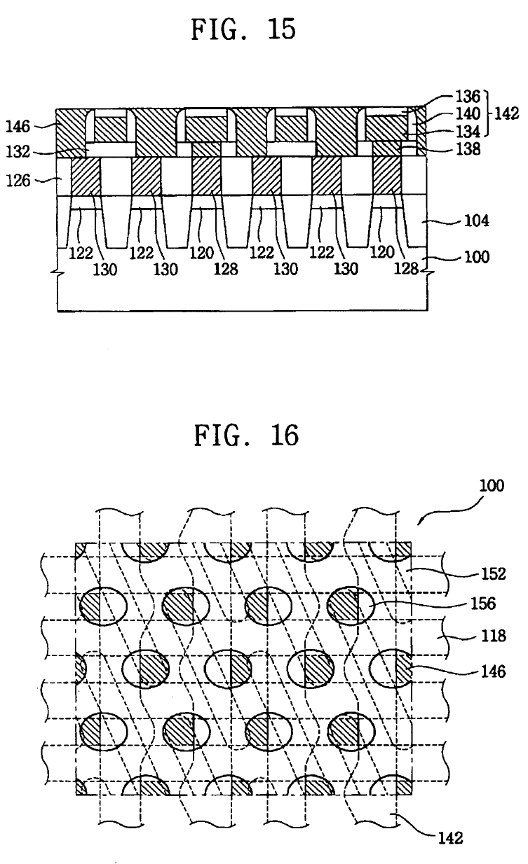

FIG. 14 is a plan view illustrating storage node contact plugs formed between the bit line structures of FIG. 11, and FIG. 15 is a cross-sectional view taken along the extension direction of the word line structures to illustrate the storage node contact plugs of FIG. 14.

Referring to FIGS. 14 and 15, a third insulation interlayer 144 is formed on the bit line structures 142 and the second insulation interlayer 132 so as to sufficiently fill up interspaces between the bit line structures 142. The third insulation interlayer 144 may comprise substantially the same material as the first and/or second insulation interlayers 126, 132. After forming the third insulation interlayer 144, an upper portion of the third insulation interlayer 144 may be removed by a CMP process (or equivalent removal process) until the bit line mask patterns 136 are exposed, thereby planarizing the third insulation interlayer 144.

A fifth photoresist pattern (not shown) is formed on the planarized third insulation interlayer 144 and the bit line mask patterns 136. The third and second insulation interlayers 144 and 132 may be sequentially patterned by an etching process using the fifth photoresist pattern as an etching mask, thereby forming storage node contact holes (not shown) exposing the second contact pads 130. The storage node contact holes extend between the bit line structures 142 and may be self-aligned to the second contact pads 130 by the bit line structures 142.

After removing the fifth photoresist pattern, a fourth contact layer (not shown) is formed on the third insulation interlayer 144 and the bit line mask patterns 136, in an effort to sufficiently fill up the storage node contact holes. Then, an upper portion of the fourth conductive layer is removed by a CMP process (or equivalent process) until the third insulation interlayer 144 and the bit line mask patterns 136 are exposed, thereby obtaining storage node contact plugs 146 (or buried contact plugs) in the storage node contact holes. The storage node contact plugs 146 may include impurity doped polysilicon or metal, for example, the storage node control plugs 146 are provided to electrically connect the second contact pads 130 with the subsequently formed storage node electrodes.

In FIG. 14, reference numeral 156 indicates openings for forming the storage node electrodes. As shown in FIG. 14, a distance D2 between each opening 156 and an adjacent storage node contact plug 146 exposed by the opening may be sufficiently secured. That is, a desired or acceptable alignment margin between the storage node contact plugs 146 and the openings 156 may be secured. Thus, two storage node contact plugs 146 may be prevented from being exposed by one opening 156.

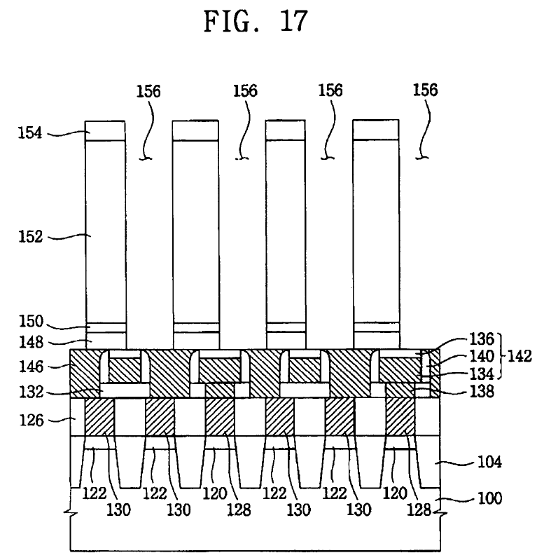

FIG. 16 is a plan view illustrating a mold layer having openings exposing the storage node contact plugs of FIG. 15, and FIG. 17 is a cross-sectional view taken along the extension direction of the word line structures to illustrate the mold layer of FIG. 16.

Referring to FIGS. 16 and 17, a fourth insulation interlayer 148 is formed on the storage node contact plugs 146, the bit line mask patterns 136 and the third insulation interlayer 144. The fourth insulation interlayer 148 is provided to electrically insulate the subsequently formed storage node electrodes of the capacitors from the asymmetric bit lines 134. The fourth insulation interlayer 148 may comprise substantially the same material as the third insulation interlayer 144.

An etch stop layer 150 is formed on the fourth insulation interlayer 148. The etch stop layer 150 may include a material having an etching selectivity with respect to the fourth insulation interlayer 148 and a mold layer 152 to be subsequently formed on the etch stop layer 150. For example, the etch stop layer 150 may include silicon nitride.

The mold layer 152 is then formed on the etch stop layer 150. The mold layer 152 may be formed to a thickness of about 5,000 to about 50,000 Å using TEOS oxide, HDP-CVD oxide, PSC, USC, BPSC; SO, etc. The height of the storage node electrodes may be determined in accordance with the thickness of the mold layer 152, and thus the thickness of the mold layer 152 may be varied in accordance with a desired capacitance of the capacitors.

A third mask layer (not shown) is formed on the mold layer 152. The third mask layer may comprise a material having an etching selectivity with respect to the mold layer 152. For example, the third mask layer may be formed to a thickness that is thicker than that the etch stop layer 150 using silicon nitride or a similar or equivalent oxide or nitride.

A sixth photoresist pattern (not shown) is formed on the third mask layer, and an etching process is then performed to partially remove the third mask layer using the sixth photoresist pattern as an etching mask, thereby forming a storage node mask pattern 154 on the mold layer 152.

After removing the sixth photoresist pattern, the mold layer 152, etch stop layer 150 and fourth insulation interlayer 148 may be sequentially patterned by an etching,process using the storage node mask pattern 154 as an etching mask, so as to form the openings 156 exposing the storage node contact plugs 146. Here, because the alignment margin between the storage node contact plugs 146 and the openings 156 is secured, two storage node contact plugs 146 may be prevented from being exposed by one opening 156. This helps to prevent an electrical bridge from being formed between the storage node electrodes.

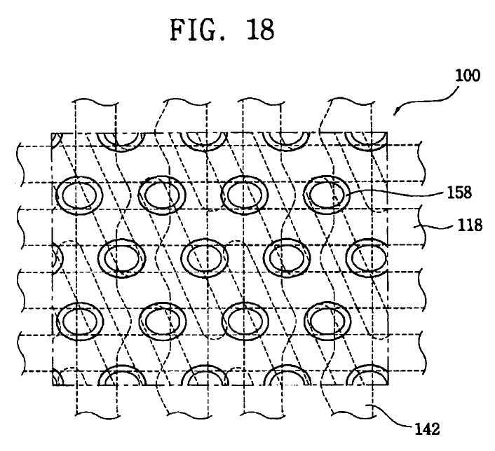

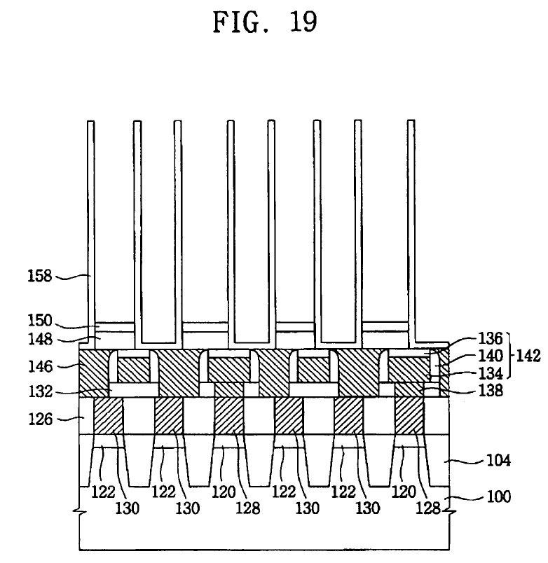

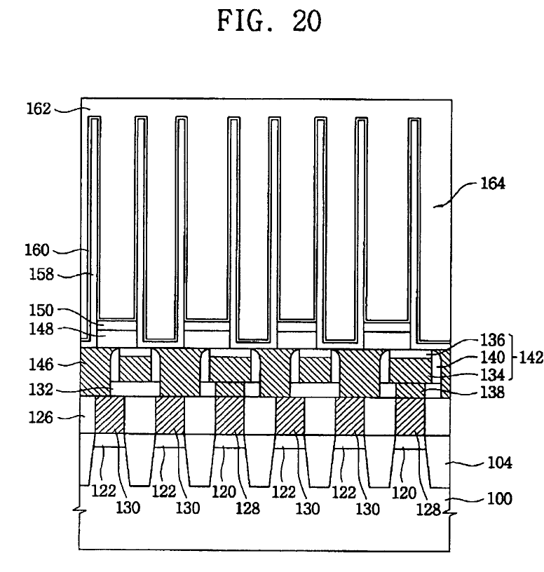

FIG. 18 is a plan view illustrating storage node electrodes formed in the openings of the mold layer as shown in FIG. 17, and FIG. 19 is a cross-sectional view taken along the extension direction of the word line structures to illustrate the storage node electrodes of FIG. 18.

Referring to FIGS. 18 and 19, a fifth conductive layer (not shown) is formed to a uniform thickness on inner surfaces of the openings 156 and the storage node mask pattern 154. A sacrificial layer (not shown) is formed on the fifth conductive layer so as to sufficiently fill up the openings 156. The sacrificial layer is formed to protect the storage node electrodes 158 while partially removing the fifth conductive layer to form the storage node electrodes 158. The sacrificial layer may comprise substantially the same material as the mold layer 152. The fifth conductive layer may include impurity doped polysilicon, a metal such as tungsten, a metal compound such as titanium nitride, etc., for example.

An upper portion of the sacrificial layer and an upper portion of the fifth conductive layer may be removed to form the storage node electrodes 158. In an example, the storage node electrodes 158 may have a cylindrical shape, although other shapes are foreseeable to one having ordinary skill in the art. The storage node electrodes 158 are electrically connected to the second impurity doped regions 122 through the storage node contact plugs 146 and the second contact pads 130.

FIG. 20 is a cross-sectional view illustrating capacitors formed on the storage node contact plugs of FIG. 19.

Referring to FIG. 20, the storage node mask pattern 154, the sacrificial layer and the mold layer 152 are removed after forming the storage node electrodes 158. The storage node mask pattern 154, the sacrificial layer and the mold layer 152 may be removed by a wet etching process or a dry etching process, and the fourth insulation interlayer 148 may be protected by the etch stop layer 150.

Then, capacitors 164 electrically connected to the transistors 124 may be constituted by sequentially forming a dielectric layer 160 and a plate electrode 162 on the storage node electrodes 158. As an example, a high-k material layer may be employed as the dielectric layer 160. High-k materials for the dielectric layer 160 may include HfD2, ZrO2, HfSiO, ZrSiO, La2O3, Ta2O5, TiO2, SrTiO3, (Ba,Sr)TiO3, etc. The plate electrode 162 may include impurity doped polysilicon, a metal such as tungsten, a metal compound such as titanium nitride, etc.

In accordance with the example embodiments of the present invention, each of the asymmetric bit lines has a first side surface extending in the straight line along the third direction and the second side surface with protrusions. Further, the protrusions may be formed above or slightly above the first contact pads and arranged in the zigzag orientation along the third direction.

Thus, a desired or acceptable alignment margin between the storage node electrodes of the capacitors and storage node contact plugs may be secured. In addition, a desired or acceptable alignment margin between the asymmetric bit lines and the first contact pads formed on the first impurity doped regions may be secured. Further, a desired or acceptable alignment margin between the second contact pads formed on the second impurity doped regions and the storage node contact plugs may be secured. Therefore, the electrical bridge phenomenon, in which adjacent storage node electrodes are electrically connected to a single storage node contact plug, may be prevented.

Although the example embodiments of the present invention have been described, it is to be understood that the present invention should not be limited to these example embodiments. Various changes and modifications can be made by one skilled in the art within the spirit and scope of the present invention as hereinafter claimed.

What is claimed is:

1. A semiconductor device, comprising:
a substrate having a plurality of active regions electronically isolated from one another by an isolation layer, each active region extending in a first direction and having a central portion between end portions;
a plurality of transistors, each including first impurity doped regions formed at the central portions and second impurity doped regions formed at both end portions of the active regions, gate insulating layer patterns formed between the first impurity doped regions and the second impurity doped regions, and word lines formed on the gate insulating layer patterns to extend in a second direction different from the first direction; and
a plurality of asymmetric bit lines electrically connected to the first impurity doped regions, wherein each of the asymmetric bit lines extends in a third direction substantially perpendicular to the second direction, has a first side surface extending in a straight line along the third direction, and has a second side surface including a plurality of protrusions.

2. The semiconductor device of claim 1, wherein the protrusions are disposed above the first impurity doped regions.

3. The semiconductor device of claim 1, wherein the first side surfaces are disposed opposite to each other.

4. The semiconductor device of claim 1, wherein the second side surfaces are disposed opposite to each other, and the protrusions are disposed in a zigzag orientation along the third direction.

5. The semiconductor device of claim 1, wherein the protrusions extend toward the end portions of active regions adjacent to the protrusions.

6. The semiconductor device of claim 1, wherein the asymmetric bit lines are electrically connected to the first impurity doped regions by a plurality of contact pads formed on the first impurity doped regions.

7. The semiconductor device of claim 1, further comprising a plurality of capacitors disposed above the asymmetric bit lines and electrically connected to the second impurity doped regions.

8. The semiconductor device of claim 7, wherein the capacitors are electrically connected to the second impurity doped regions by a plurality of contact pads and a plurality of contacts plugs formed on the second impurity doped regions.

9. The semiconductor device of claim 8, wherein the contact plugs extend from the contact pads between the asymmetric bit lines.

10. A method of manufacturing a semiconductor device, comprising:
forming an isolation layer on a substrate to define a plurality of active regions isolated from one another, each active region extending in a first direction and having a central portion between end portions;
forming a plurality of gate insulating layer patterns and word lines between the central portions and end portions of the active regions, the word lines extending in a second direction different from the first direction;
forming a plurality of first impurity doped regions at the central portions and a plurality of second impurity doped regions at the end portions of the active regions; and
forming a plurality of asymmetric bit lines electrically connected to the first impurity doped regions, wherein each of the asymmetric bit lines extends in a third direction substantially perpendicular to the second direction, has a first side surface extending in a straight line along the third direction, and has a second side surface including a plurality of protrusions.

11. The method of claim 10, wherein the protrusions of the asymmetric bit lines are disposed just above the first impurity doped regions.

12. The method of claim 10, wherein the asymmetric bit lines are formed so that the first side surfaces are disposed opposite each other.

13. The method of claim 10, wherein the asymmetric bit lines are formed so that the second side surfaces are disposed opposite each other, and the protrusions are disposed in a zigzag orientation along the third direction.

14. The method of claim 10, further comprising:
forming first contact pads on the first impurity doped regions and second contact pads on the second impurity doped regions; and
forming bit line contact plugs-on the first contact pads to electrically connect the asymmetric bit lines with the first contact pads.

15. The method of claim 14, further comprising:
forming storage node contact plugs on the second contact pads so as to extend between the asymmetric bit lines; and
forming a plurality of capacitors above the asymmetric bit lines that are electrically connected to the second impurity doped regions by the storage node contact plugs and the second contact pads.

16. A semiconductor device, comprising:
a substrate having active regions, each active region having a central portion between end portions;
a plurality of transistors, each transistor including an impurity doped region formed at the central portion of a given active region and a word line formed between the central and end portions and extending in a given direction different than an extension direction of the active regions; and
a plurality of asymmetric bit lines connected to the impurity doped regions, each bit line extending in a direction perpendicular to the word lines and including a first side surface and a second side surface, the second side surface including a plurality of protrusions.

17. The device of claim 16, wherein
the protrusions are disposed above the first impurity doped regions in a zigzag orientation along the third direction;
the first side surfaces are disposed opposite to each other; and
the second side surfaces are disposed opposite to each other.

18. The device of claim 16, wherein each transistor further includes second impurity doped regions formed at each end of a given active region.

19. The device of claim 18, wherein
the asymmetric bit lines are electronically connected to the first impurity doped regions by a plurality of contact pads formed on the first impurity doped regions; and
a plurality of capacitors are disposed above the asymmetric bit lines and electronically connected to the second impurity doped regions.

20. The device of claim 19, wherein the capacitors are electronically connected to the second impurity doped regions by a plurality of contact pads and a plurality of contacts plugs formed on the second impurity doped regions.

21. A method of forming a semiconductor device, comprising:
forming a plurality of active regions on a substrate, each active region having a central portion between end portions;
forming word lines between the central and end portions of the active regions;
forming a plurality of impurity doped regions at the central portions of the active regions; and
forming a plurality of asymmetric bit lines connected to the impurity doped regions, each asymmetric bit line extending in a direction perpendicular to the word line and including a side surface having a plurality of protrusions thereon.
